(19) United States
(12) Patent Application Publication
(10) Pub. No.: US 2024/0399712 A1
(43) Pub. Date: Dec. 5, 2024

(54) COMPOSITE FOAM STRUCTURE AND DISPLAY MODULE

(71) Applicants: Chengdu BOE Optoelectronics Technology Co., Ltd., Chengdu, Sichuan (CN); BOE Technology Group Co., Ltd., Beijing (CN)

(72) Inventors: Baofu LU, Beijing (CN); Renzhe XU, Beijing (CN); Wei GONG, Beijing (CN); Wei LIU, Beijing (CN); Danyang BI, Beijing (CN); Han ZHANG, Beijing (CN); Inho PARK, Beijing (CN)

(21) Appl. No.: 18/697,995

(22) PCT Filed: Aug. 1, 2023
(86) PCT No.: PCT/CN2023/110484

§ 371 Date: Apr. 2, 2024

(30) Foreign Application Priority Data
Sep. 19, 2022 (CN) 202211136628.5

(51) Int. Cl. B32B 15/04; B32B 5/12; B32B 7/12; B32B 37/12; H10K 59/126; H10K 59/80

(52) U.S. Cl. CPC B32B 15/046; B32B 5/12; B32B 7/12; B32B 37/12; H10K 59/873; B32B 2037/1253; B32B 2262/106; B32B 2305/022; B32B 2457/20; H10K 59/126

(57) ABSTRACT

A composite foam structure is provided. The composite foam structure includes a foam layer, a metal layer, and a first adhesive layer, the first adhesive layer being disposed between the foam layer and the metal layer and configured to bond g the foam layer and the metal layer; wherein the composite foam structure further includes a fiber structure, wherein the fiber structure is disposed in at least one of the foam layer or the first adhesive layer and configured to increase a tensile strength of at least one of the foam layer or the first adhesive layer.

### CROSS-REFERENCE TO RELATED APPLICATIONS

This application is a U.S. national stage of international application No. PCT/CN2023/110484, filed on Aug. 1, 2023, which claims priority to Chinese Patent Application No. 202211136628.5, filed on Sep. 19, 2022, and entitled “COMPOSITE FOAM STRUCTURE AND DISPLAY MODULE,” the disclosures of which are herein incorporated by reference in their entireties.

### TECHNICAL FIELD

The present disclosure relates to the field of display manufacturing, and in particular, to a composite foam structure and a display module.

### BACKGROUND

As display products using active-matrix organic light-emitting diode (AMOLED) display modules become more popular, users are demanding thinner and lighter AMOLED display modules.

### SUMMARY

Embodiments of the present disclosure provide a composite foam structure and a display module.

According to some embodiments of the present disclosure, a composite foam structure is provided. The composite foam structure includes a foam layer, a metal layer, and a first adhesive layer, the first adhesive layer being disposed between the foam layer and the metal layer and configured to bond the foam layer to the metal layer; wherein the composite foam structure further comprises a fiber structure, wherein the fiber structure is disposed in at least one of the foam layer or the first adhesive layer and configured to increase a tensile strength of at least one of the foam layer or the first adhesive layer.

In some embodiments, the fiber structure includes at least one layer of a carbon fiber network formed by a plurality of carbon fibers staggered in a designated plane.

In some embodiments, each of the carbon fibers has a diameter ranging from greater than or equal to 5 μm to less than or equal to 7 μm.

In some embodiments, the designated plane is parallel to at least one of a plane in which the foam layer is located or a plane in which the first adhesive layer is located.

In some embodiments, an angle between two intersectant carbon fibers is greater than or equal to 30° and less than or equal to 90°.

In some embodiments, the angle between the two intersectant carbon fibers is 60°.

In some embodiments, the composite foam structure further includes a light-shielding tape layer, wherein the light-shielding tape layer is disposed on a side, distal from the metal layer, of the foam layer.

In some embodiments, the light-shielding tape layer includes an Embo-type adhesive layer.

In some embodiments, the composite foam structure further includes a second adhesive layer and a substrate layer, wherein the second adhesive layer is disposed between the metal layer and the substrate layer, and the substrate layer is configured to protect the second adhesive layer.

In some embodiments, a material of the second adhesive layer includes an ultraviolet curing adhesive.

In some embodiments, a material of the first adhesive layer includes a pressure-sensitive adhesive.

In some embodiments, a material of the foam layer includes a super clean foam.

According to some embodiments of the present disclosure, a display module is further provided. The display module includes a display panel, a backplane, and the above composite foam structure provided by the present disclosure, wherein the composite foam structure is disposed between the display panel and the backplane.

### BRIEF DESCRIPTION OF DRAWINGS

FIG. 1 is a structural schematic diagram of a composite foam structure in the prior art;

FIG. 2 is a schematic diagram of a composite foam structure of the prior art in the case that the impression occurs during the manufacturing process;

FIG. 3 is a structural schematic diagram of a composite foam structure according to some embodiments of the present disclosure;

FIG. 4A is a top view of a carbon fiber network according to some embodiments of the present disclosure;

FIG. 4B is a force analysis diagram of a carbon fiber network according to some embodiments of the present disclosure;

FIG. 5A is a top view of another carbon fiber network according to some embodiments of the present disclosure; and

FIG. 5B is a force analysis diagram of another carbon fiber network according to some embodiments of the present disclosure.

### DETAILED DESCRIPTION

The present disclosure is described in detail hereinafter, and examples of embodiments of the present disclosure are shown in the accompanying drawings, wherein the same or similar symbols or numerals throughout denote the same or similar components or components having the same or similar functions. Furthermore, detailed descriptions of the known art are omitted in the case that they are not necessary for the illustrated features of the present disclosure. The embodiments described below by reference to the accompanying drawings are exemplary and are intended to explain the present disclosure and are not to be construed as a limitation of the disclosure.

It is understandable by those skilled in the art that, unless otherwise defined, all terms used in the present embodiments, including technical and scientific terms, have the same meaning as is generally understood by those of ordinary skill in the art to which the present disclosure belongs. It should also be understood that terms such as those defined in general-purpose dictionaries are to be understood as having a meaning consistent with that in the context of the prior art and are not to be interpreted in an idealized or overly formalized sense unless specifically defined as herein.

In the relative art, one way to thin the display module is thinning the composite foam structure, including but not limited to, super clean foam (SCF) attached to the back of the display panel, wherein the composite foam structure is configured to achieve a buffering effect. However, thinning the composite foam structure may lead to a reduction in strength. Specifically, the thinner the composite foam structure, the softer the overall structure, and the more the overall structure is prone to deformation. During a die-cutting production process, in the case that the production equipment is provisionally halted, the thinner composite foam structure produces roller profiling deformation due to pressing on the stacked layers. That is, impressions under halting states easily occur, which results in poor impressions. A serious poor impression leads to the scarp of the composite foam structure scrap. The composite foam structure with a slight impression defect enters the subsequent display module production process, but positions corresponding to the impression defect bulge, resulting in a decrease in the quality of the display module.

Embodiments of the present disclosure are intended to solve at least one of the technical problems in the relative art. A composite foam structure and a display module are provided, which can reduce the thickness, and at the same time avoid poor impression of the composite foam structure.

In order to enable those skilled in the art to better understand the technical solutions of the present disclosure, the composite foam structure and display module provided by the present disclosure are described in detail hereafter in conjunction with the accompanying drawings.

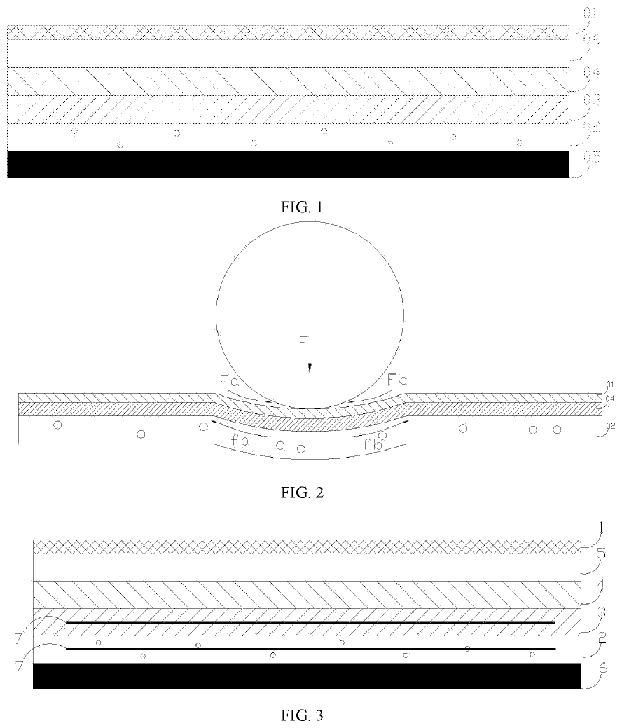

As shown in FIG. 1, the conventional composite foam structure includes a substrate layer 01 and a second adhesive layer 06, a metal layer 04, a first adhesive layer 03, a foam layer 02, and a light-shielding tape layer 05 disposed sequentially in a direction away from the substrate layer 01. Correspondingly, the manufacturing processes of the conventional composite foam structure generally include: pressing the above plurality of stacked layers of the composite foam structure and then die-cutting the same. Specifically, as shown in FIG. 2, in the case that the production equipment is employed to press-fit the conventional composite foam structure, the rollers of the production equipment rotate about a specified axis to apply pressure F to the upper surface of the composite foam structure during translation of the composite foam structure, so as to cause the plurality of stacked layers in the composite foam structure to be closely affixed together. Because the composite foam structure is in motion all the time, the plurality of stacked layers of the composite foam structure are briefly pressed at various positions of the surface, and thus there is no risk of forming an imprint.

However, in actual production, due to equipment changing material, sudden failure, personnel handover, or other circumstances, the production equipment is inevitably subject to a shutdown, and the length of the shutdown ranges from about a few minutes to dozens of minutes. In order to ensure the accuracy of the subsequent process and production efficiency, in the case that the production equipment is halted, the pressure of the roller can not be released, to enable the roller to fix the composite foam structure, so that upon the re-opening of the production equipment, the process can be immediately continued, thereby ensuring the continuity of the process. However, in the case that the production equipment is temporarily stopped, the rollers constantly apply pressure to the same position of the composite foam structure. Because the foam layer 02 and the first adhesive layer 03 in the composite foam structure have a certain degree of elasticity, in the case of being pressed for a period of time, the foam layer 02 and the first adhesive layer 03 can still recover to the form before pressing upon the pressure being removed. However, the metal layer 04 in the composite foam structure has low elasticity and a certain degree of plasticity. Therefore, in the case of being subjected to pressure and generating a deformation for a long period of time, and the pressure exceeding the yield deformation of the metal layer 04, a downward depression is usually formed on the metal layer 04, i.e., transversal stretching and longitudinal bending are occurred, which results in irrecoverable shear strain at the boundary of the force on the metal layer 04, and then produces permanent plastic deformation, i.e., produces an impression defect. Moreover, the degree of depression of the metal layer 04 is related to the suspension time of the production equipment. A heavy degree of depression possibly leads to the scrapping of the composite foam structure. A light degree of depression is not easy to detect, therefore the composite foam structure possibly enters the subsequent display module manufacturing process or even the whole machine manufacturing process, resulting in the occurrence of a bulge on the display module, thus affecting the quality of the display module.

The inventor has found that: taking the production process of the traditional composite foam structure shown in FIG. 2 as an example, in the case that the production equipment temporarily stops, the roller continues to apply pressure F on a same position of the composite foam structure, the pressure F is divided into two tilted downward forces Fa and Fb, resulting in that part of the stacked layers of the composite foam structure generate the stretching deformation tendency toward two sides of the position to which the force is applied as shown in FIG. 2, so that two tensions fa and fb in opposite directions to the above-described two partial forces Fa and Fb are generated in a part of the stacked layers to support the metal layer 04, assist the metal layer 04 in resisting external forces, and reduce the plastic deformation of the metal layer 04. However, because the foam layer 02 in the conventional composite foam structure is foamed, both the foam layer and the first adhesive layer 03 (generally a pressure-sensitive adhesive) have a relatively low tensile strength, the effect of assisting the metal layer 04 in resisting the external force is highly limited, and thus the problem of poor impression can not be solved.

In order to solve the above technical problems, the present embodiments provide a composite foam structure. As shown in FIG. 3, the composite foam structure includes a foam layer 2, a metal layer 4, and a first adhesive layer 3, wherein the first adhesive layer 3 is disposed between the foam layer 2 and the metal layer 4 and configured to bond the foam layer 2 to the metal layer 4. The metal layer 4 has the functions of resisting impact, enhancing the overall strength of the composite foam structure, heat dissipation, and grounding. The selection of the material of the metal layer 4 is not limited in the embodiments of the present disclosure, the material includes such as copper, aluminum, steel, and the like. In some embodiments, the thickness of the metal layer 4 is greater than or equal to 10 μm and less than or equal to 50 μm.

In some optional embodiments, a material of the first adhesive layer 3 includes a pressure-sensitive adhesive (PSA), which is used to bond the foam layer 2 and the metal layer 4, and has a heat dissipation effect. The thickness of the first adhesive layer 3 is designed depending on the specific thickness of the metal layer 4, the thicker the metal layer 4 is, the thicker the first adhesive layer 3 is; conversely, the thinner the metal layer 4 is, the thinner the first adhesive layer 3 is. In some embodiments, the thickness of the metal layer 4 is greater than or equal to 10 μm and less than or equal to 20 μm.

In some optional embodiments, a material of the foam layer 2 includes a super clean foam (SCF), which has a stronger impact resistance relative to the foamed foam and is used to serve as the cushion in the case that the composite foam structure is subjected to an impact force.

As shown in FIG. 3, the composite foam structure in the embodiments further includes fiber structures 7, which are disposed in the foam layer 2 and the first adhesive layer 3 respectively, for improving the tensile strengths of the foam layer 2 and the first adhesive layer 3. In this way, during the die-cutting production process, in the case that the composite foam structure is subjected the pressure of the rollers due to the shutdown of the production equipment, the foam layer 2 and the first adhesive layer 3, due to the sufficient tensile strength, play a role in supporting the metal layer 4, assisting the metal layer 4 to resist the external forces, and reducing the plastic deformation of the metal layer 4, thereby improving the overall tensile strength of the composite foam structure, to reduce the risk of deformation of the composite foam structure due to being pressed, reducing the occurrence of impression defects, and thus improving the yield of the composite foam structure. On this basis, by providing the fiber structures 7 in the foam layer 2 and the first adhesive layer 3, the overall thickness of the composite foam structure is reduced on the premise of improving the tensile strength of the foam layer 2 and the first adhesive layer 3, so as to ensure that the thickness of the display module to which the composite foam structure is applied is not too large, which is, in turn, conducive to the lightness and thinness of the display module.

In some other optional embodiments, the above fiber structure 7 is disposed only in the foam layer 2, or only in the first adhesive layer 3, which similarly plays a role in assisting the metal layer 4 to resist external forces and reduces the plastic deformation of the metal layer 4. It is understandable that providing the fiber structures 7 in both the foam layer 2 and the first adhesive layer 3 is more effective in assisting the metal layer 4 to resist the external force and reducing the plastic deformation of the metal layer 4.

Moreover, compared to the way of thickening the foam layer 2 to support the metal layer 4, the present embodiments, by disposing the fiber structures 7 in at least one of the foam layer 2 or the first adhesive layer 3, is able to enhance the tensile strength of at least one of the foam layer 2 or the first adhesive layer 3, and at the same time, ensure that at least one of the thickness of the foam layer 2 or the thickness of the first adhesive layer 3 does not increase, so as to reduce the overall thickness of the composite foam structure, which ensures that the thickness of the display module to which the composite foam structure is applied is not too large, and thus facilitates the thinning and lighting of the display module. It has been found through experiments that, compared to enhancing the effect of supporting the metal layer 4 by thickening the foam layer 2, the present embodiments, by providing the fiber structures 7 in at least one of the foam layer 2 or the first adhesive layer 3, achieve a thinning amount of the foam layer 2 (relative to the foam layer without the fiber structure) by 10 μm-20 μm, and a thinning amount of the first adhesive layer 3 (relative to the first adhesive layer without the fiber structure) by 5 μm-10 μm.

The inventor has found through multiple tests that each carbon fiber in the carbon fiber network has a range from greater than or equal to 5 μm to less than or equal to 7 μm; the thickness of the metal layer ranges from 10 μm to 50 μm, and the thickness of the first adhesive layer ranges from 10 μm to 20 μm. Under these conditions, the foam layer in the conventional composite foam structure (not set with the carbon fiber network) is compared to the foam layer 2 in the composite foam structure adopted in the present embodiments, the overall tensile strength of the foam layer in the conventional composite foam structure is about 0 to 0.50 MPa, and the tensile strength of the foam layer 2 in the composite foam structure adopted in the present embodiments is able to reach 0.60 MPa to 0.63 MPa by disposing the carbon fiber network, which thereby effectively improves the overall tensile strength of the composite foam structure.

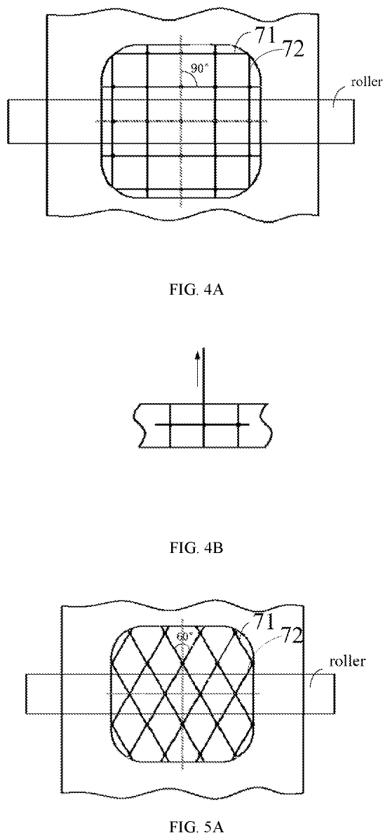

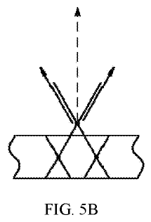

In some optional embodiments, the above-described fiber structure 7 includes at least one layer of a carbon fiber network formed by a plurality of carbon fibers staggered in a designated plane. In some embodiments, as shown in FIG. 4A and FIG. 5A, the plurality of carbon fibers include a plurality of first carbon fibers 71 disposed in a first direction within the designated plane, and a plurality of second carbon fibers 72 disposed in a second direction within the designated plane, wherein the first carbon fiber 71 and the second carbon fiber 72 intersect with each other, and are connected at the intersection point. In some embodiments, the above-designated plane is parallel to the plane in which the foam layer 2 (where the carbon fiber network is disposed) is located or the plane in which the first adhesive layer 3 (where the carbon fiber network is disposed) is located. In this way, in the case that the carbon fiber network is subjected to external pressure (e.g., from the roller), the carbon fiber network is perpendicular to the external pressure, and a uniform stress is generated at the position where the force is applied on the carbon fiber network, thereby counteracting the external pressure to the greatest extent.

In some optional embodiments, an angle between two intersectant carbon fibers (i.e., the first carbon fiber 71 and the second carbon fiber 72) is greater than or equal to 30° and less than or equal to 90°.

Specifically, the contact between the roller and the composite foam structure is line contact, i.e., the contact position is between an axial straight line on the outer peripheral face of the roller and the surface of the composite foam structure. As shown in FIG. 2, during the die-cutting production process, in the case of being subjected to the pressure of the roller due to the shutdown of the production equipment, the composite foam structure tends to bend downwardly as well as stretch transversely at the contact position. Accordingly, the portions of the carbon fiber network located at two sides of the contact position generate two tensions fa and fb that are perpendicular to the straight line at which the contact position is. The tension generated by each of the carbon fibers in the carbon fiber network depends on the extension direction of the carbon fiber, based on this, the above two tensions fa and fb are combined forces of the tensions of the multiple carbon fibers at two sides of the contact position. Furthermore, the angle between the two intersectant carbon fibers in the carbon fiber network is selected based on the actual force applied to the carbon fiber network.

Taking the carbon fiber network shown in FIG. 4A as an example, the angle between the intersectant first carbon fiber 71 and the second carbon fiber 72 is, in some embodiments, 90°. In the case that the carbon fiber network is subjected to an external pressure (e.g., from a roller), as shown in FIG. 4B, the two tensions fa and fb generated by the carbon fiber network are inevitably parallel to the stress generated by one of the first carbon fiber 71 and the second carbon fiber 72, and perpendicular to the stress generated by the other. In this case, the external pressure on the carbon fiber network is offset by the stress generated internally in one of the first carbon fiber 71 and the second carbon fiber 72 that are perpendicular to the straight line in which the contact position is located, and the other of the first carbon fiber 71 and the second carbon fiber 72 almost do not generate stress. That is, only one of the first carbon fiber 71 and the second carbon fiber 72 serves as a resistance to the external force, such that the tensile strength of the carbon fiber network is low. In this regard, in some preferred embodiments, the angle between the intersectant first carbon fiber 71 and the second carbon fiber 72 is less than 90°. In some embodiments, as shown in FIG. 5B, the angle between the intersectant first carbon fiber 71 and second carbon fiber 72 in the carbon fiber network is 60°. In the case that the carbon fiber network is subjected to external pressure, because the angle between the first carbon fiber 71 and the straight line where the above contact position is located and the angle between the second carbon fiber 72 and the straight line where the above contact position is located are all 60°, each of the first carbon fiber 71 and the second carbon fiber 72 located on both sides of the contact position generates stress internally, and the combined force thereof is equal to the external pressure on the carbon fiber network. That is, the external pressure applied on the carbon fiber network is offset by stresses internally generated by all of the carbon fibers located on both sides of the contact position, with various carbon fibers generating smaller and equal stress, thereby allowing the tensile strength of the carbon fiber network to be increased as much as possible, and increasing the service life of the carbon fiber network.

It is found through testing that: in the case that the angle between the intersectant first carbon fiber 71 and second carbon fiber 72 is 90°, the tensile strength of the foam layer 2 reaches 0.60 MPa, and the tensile strength of the second adhesive layer 3 reaches 0.68 MPa; and in the case that the angle between the intersectant first carbon fiber 71 and the second carbon fiber 72 is 60°, the tensile strength of the foam layer 2 reaches 0.63 MPa, and the tensile strength of the second adhesive layer 3 is able to reach 0.70 MPa. As can be seen, in the case that the angle between the intersectant first carbon fiber 71 and second carbon fiber 72 is 60°, the tensile strength of the carbon fiber network is further improved.

In some optional embodiments, each carbon fiber in the carbon fiber network has a diameter ranging from greater than or equal to 5 μm to less than or equal to 7 μm. Specifically, the carbon fibers with diameters in the range occupy less space, so as not to affect the compression force deflection (CFD) of the foam layer 2, and thus not to affect the ability of the foam layer 2 to cushion external forces. As can be seen from tests, the stress of the foam layer in the traditional composite foam structure in the case of 25% of the compression force deflection (CFD) occurring is about 0.32 MPa, and the stress of the foam layer 2 in the composite foam structure adopted in the embodiments in the case of 25% of the compression force deflection (CFD) occurring is about 0.31 MPa, which is almost the same as the traditional composite foam structure. Therefore, it can be seen that the setting of the carbon fiber structure does not affect the compression force deflection of the foam layer 2, which in turn does not affect the ability of the foam layer 2 to cushion external forces.

In addition, the carbon fiber network with a diameter within the above range does not affect the adhesion of the first adhesive layer 3, and effectively improves the tensile strength of the first adhesive layer 3. As can be seen from tests, the transverse tensile stress (tensile strength) of the first adhesive layer in the conventional composite foam structure in the case of being subjected to a peeling force of 1500 gf/inch is 0.6 Mpa; and the transverse tensile stress (tensile strength) of the first adhesive layer 3 in the composite foam structure adopted in the present embodiments in the case of being subjected to a peeling force of 1500 gf/inch is 0.68 Mpa-0.70 Mpa. It can be seen that the tensile strength of the first adhesive layer 3 is effectively enhanced by setting the carbon fiber structure.

Further, due to the smaller diameter of the carbon fibers, in some embodiments, the number of layers of the carbon fiber network is appropriately increased, so that the tensile strength of the carbon fiber structure is further improved. Specifically, the tensile strengths of the foam layer 2 and the first adhesive layer 3 increase as the number of layers of the carbon fiber network increases.

In some optional embodiments, the fiber structure 7 is made by means of textile. Additionally, in some embodiments, the method for disposing the fiber structures 7 in at least one of the foam layer 2 or the first adhesive layer 3 includes:
preparing at least one of the foam sol or the first adhesive layer sol;
tensioning the pre-fabricated fiber structure 7 and immersing the fiber structure 7 in at least one of the above-mentioned foam sol or first adhesive layer sol; and
forming at least one of the foam layer 2 or the first adhesive layer 3 by curing at least one of the foam sol or the first adhesive layer sol.

In some optional embodiments, as shown in FIG. 3, the composite foam structure further includes a second adhesive layer 5 and a substrate layer 1, wherein a material of the substrate layer 1 includes PET (Polyethylene terephthalate). The substrate layer 1 itself has a certain tension, so that the substrate layer 1 is able to resist deformation in the case of being subjected to an external pressure, and in turn assist the metal layer 4 adhered thereto in resisting deformation, thereby further reducing the risk of poor impression of the metal layer 4. The second adhesive layer 5 is disposed between the metal layer 4 and the substrate layer 1, and the substrate layer 1 is configured to protect the second adhesive layer 5. In practice, in the case that the composite foam structure is used, the substrate layer 1 is first peeled off from the second adhesive layer 5, and then the second adhesive layer 5 is adhered to a corresponding product (e.g., a side, away from the light-emitting surface, of a display panel).

Please return to refer to FIG. 1, in the conventional composite foam structure, the second adhesive 06 used to bond the substrate layer 01 to the metal layer 04 usually has a very low peeling force of about 10 gf/inch, which leads to insufficient adhesion between the substrate layer 01 and the metal layer 04, and in turn, results that the substrate layer 01 is only able to cover the metal layer 04 in a direction perpendicular to the surface of the metal layer 04, but hard to resist the transversal slippage in a direction parallel to the surface of the metal layer 04. Therefore, in the case that the roller applies pressure to the conventional composite foam structure, the substrate layer 01 detaches from the metal layer 04 due to the tension in the substrate layer. Moreover, in practice, the substrate layer 01 in the conventional composite foam structure is highly susceptible to detachment, and difficult to pass a holding force test.

In order to solve this technical problem, in the composite foam structure provided by the embodiments of the present disclosure, a material of the second adhesive layer 5 includes an ultraviolet light curing adhesive (i.e., UV adhesive). Specifically, the peeling force of the UV adhesive is greater than or equal to 2000 gf/inch. With the aid of the UV adhesive, the metal layer 4 is hard to slip and move relative to the substrate layer 1, so that the substrate layer 1 does not detach from the metal layer 4 in the case that the roller applies pressure to the composite foam structure.

In some optional embodiments, as shown in FIG. 3, the composite foam structure according to the embodiments of the present disclosure further includes a light-shielding tape layer 6, which is disposed on the side, distal from the metal layer 4, of the foam layer 2, for adhering to the backplane of the display module or any other product. In some embodiments, the light-shielding tape layer 6 includes an Embo-type adhesive layer.

In summary, the composite foam structure provided by the embodiments of the present disclosure improves the tensile strength of at least one of the foam layer or the first adhesive layer by disposing a fiber structure in at least one of the foam layer or the first adhesive layer. In this way, during the die-cutting process, in the case that the composite foam structure is subjected to the pressure of the rollers due to the halt of the production equipment, at least one of the foam layer or the first adhesive layer, due to sufficient tensile strength, plays a role in supporting the metal layer, assisting the metal layer to resist the external force, and reducing the plastic deformation of the metal layer, thereby improving the overall tensile strength of the composite foam structure, reducing the deformation risk of composite foam structure caused by pression, reducing the occurrence of poor impressions, and thus improving the yield of the composite foam structure. On this basis, by providing the fiber structure in at least one of the foam layer or the first adhesive layer, the overall thickness of the composite foam structure is reduced on the premise of improving the tensile strength of at least one of the foam layer or the first adhesive layer, so that the thickness of the display module to which the composite foam structure is applied is not too large, and thus the lightness and thinness of the display module can be easily achieved.

As another technical solution, the embodiments of the present disclosure further provide a display module. The display module includes a display panel, a backplane, and the above composite foam structure provided by the embodiments of the present disclosure. Therein, the composite foam structure is disposed between the display panel and the backplane for fixing and protecting the display panel.

Specifically, when installing the composite foam structure, the substrate layer 1 needs to be peeled off first, and then the first adhesive layer 3 is attached to a side, away from the light-emitting surface, of the display panel; and the light-shielding tape layer 6 is adhered to the backplane.

By adopting the above composite foam structure provided by the embodiments of the present disclosure, the display module provided by the embodiments of the present disclosure can not only have an improved quality but also have a thinner and lighter size.

It is understandable that the above embodiments are merely exemplary embodiments for the purpose of illustrating the principles of the present disclosure. However, the present disclosure is not limited to the above embodiments. For a person of ordinary skill in the art, various variations and improvements may be made without departing from the concept and substance of the present disclosure, and these variations and improvements are also considered within the scope of protection of the present disclosure.

1. A composite foam structure, comprising a foam layer, a metal layer, and a first adhesive layer, the first adhesive layer being disposed between the foam layer and the metal layer and configured to bond the foam layer to the metal layer;
wherein the composite foam structure further comprises a fiber structure, wherein the fiber structure is disposed in at least one of the foam layer or the first adhesive layer and configured to increase a tensile strength of at least one of the foam layer or the first adhesive layer.

2. The composite foam structure according to claim 1, wherein the fiber structure comprises at least one layer of a carbon fiber network formed by a plurality of carbon fibers staggered in a designated plane.

3. The composite foam structure according to claim 2, wherein each of the carbon fibers has a diameter ranging from greater than or equal to 5 μm to less than or equal to 7 μm.

4. The composite foam structure according to claim 2, wherein the designated plane is parallel to at least one of a plane in which the foam layer is located or a plane in which the first adhesive layer is located.

5. The composite foam structure according to claim 2, wherein an angle between two intersectant carbon fibers is greater than or equal to 30° and less than or equal to 90°.

6. The composite foam structure according to claim 5, wherein the angle between the two intersectant carbon fibers is 60°.

7. The composite foam structure according to claim 1, further comprising a light-shielding tape layer, wherein the light-shielding tape layer is disposed on a side, distal from the metal layer, of the foam layer.

8. The composite foam structure according to claim 7, wherein the light-shielding tape layer comprises an Embo-type adhesive layer.

9. The composite foam structure according to claim 1, further comprising a second adhesive layer and a substrate layer, wherein the second adhesive layer is disposed between the metal layer and the substrate layer, and the substrate layer is configured to protect the second adhesive layer.

10. The composite foam structure according to claim 9, wherein a material of the second adhesive layer comprises an ultraviolet curing adhesive.

11. The composite foam structure according to claim 1, wherein a material of the first adhesive layer comprises a pressure-sensitive adhesive.

12. The composite foam structure according to claim 1, wherein a material of the foam layer comprises a super clean foam.

13. A display module, comprising a display panel, a backplane, and a composite foam structure, wherein the composite foam structure is disposed between the display panel and the backplane, and the composite foam structure comprises a foam layer, a metal layer, and a first adhesive layer, the first adhesive layer being disposed between the foam layer and the metal layer and configured to bond the foam layer to the metal layer;
wherein the composite foam structure further comprises a fiber structure, wherein the fiber structure is disposed in at least one of the foam layer or the first adhesive layer and configured to increase a tensile strength of at least one of the foam layer or the first adhesive layer.

14. The display module according to claim 13, wherein the fiber structure comprises at least one layer of a carbon fiber network formed by a plurality of carbon fibers staggered in a designated plane.

15. The display module according to claim 14, wherein each of the carbon fibers has a diameter ranging from greater than or equal to 5 μm to less than or equal to 7 μm.

16. The display module according to claim 14, wherein the designated plane is parallel to at least one of a plane in which the foam layer is located or a plane in which the first adhesive layer is located.

17. The display module according to claim 14, wherein an angle between two intersectant carbon fibers is greater than or equal to 30° and less than or equal to 90°.

18. The display module according to claim 17, wherein the angle between the two intersectant carbon fibers is 60°.

19. The display module according to claim 13, wherein the composite foam structure further comprises a light-shielding tape layer, wherein the light-shielding tape layer is disposed on a side, distal from the metal layer, of the foam layer.

20. The display module according to claim 19, wherein the light-shielding tape layer comprises an Embo-type adhesive layer.
